(19) United States
(12) Patent Application Publication
(10) Pub. No.: US 2018/0151714 A1
(43) Pub. Date: May 31, 2018

(54) NITRIDE SEMICONDUCTOR SUBSTRATE

(71) Applicant: CoorsTek KK, Tokyo (JP)

(72) Inventors: Noriko OMORI, Kanagawa (JP); Hiroshi OISHI, Kanagawa (JP); Yoshihisa ABE, Kanagawa (JP); Jun KOMIYAMA, Kanagawa (JP)

(73) Assignee: CoorsTek KK, Tokyo (JP)

(21) Appl. No.: 15/816,844

(22) Filed: Nov. 17, 2017

(30) Foreign Application Priority Data
Nov. 30, 2016 (JP) 2016-232090
Sep. 1, 2017 (JP) 2017-168182

(51) Int. Cl. H01L 29/778; H01L 29/20; H01L 29/205

(52) U.S. Cl. CPC H01L 29/7787; H01L 29/205; H01L 29/2003

(57) ABSTRACT

Provided is a nitride semiconductor substrate which improves electron mobility and reduce a series resistance component of a transistor. In the nitride semiconductor substrate, an electron transit layer, an intermediate layer, and an electron supply layer are laminated in this order. The electron transit layer includes a nitride semiconductor of a first group 13 element. The intermediate layer and the electron supply layer each include a nitride semiconductor of the first group 13 element and a second group 13 element. The nitride semiconductor substrate has a profile in which an atomic ratio of the second group 13 element to a total of the first group 13 element and the second group 13 element increases in the thickness direction of the intermediate layer from an interface between the electron transit layer and the intermediate layer, and the atomic ratio decreases after a maximum peak value is obtained in the intermediate layer.

### BACKGROUND OF THE INVENTION

### Field of the Invention

The present invention relates to a substrate structure for improving device characteristics in a nitride semiconductor substrate for a power device that can be increased in high frequency and high output.

### Description of the Related Art

In a high electron mobility transistor (HEMT) using a nitride semiconductor, particularly a gallium nitride-based compound semiconductor substrate, a technique is known which improves electric characteristics by interposing a so-called spacer layer between an electron transit layer and an electron supply layer.

JP 2004-200711 A discloses a technique that a nitride-based III-V group compound semiconductor device having a heterostructure includes a first binary compound semiconductor layer forming a channel layer, a ternary mixed crystal semiconductor layer forming a barrier layer and including AlGaN in which a composition ratio of Al and Ga is constant, and a second binary compound semiconductor layer interposed between the first binary compound semiconductor layer and the ternary mixed crystal semiconductor layer. The first binary compound semiconductor layer includes GaN. The second binary compound semiconductor layer includes AlN, and has a layer thickness of 1 molecular layer or more and 4 molecular layer or less.

JP 2003-229439 A discloses a compound semiconductor device. The compound semiconductor device has a structure in which an electron supply layer, a spacer layer, and a channel layer each of which includes a nitride of a group III element essentially containing Ga are joined in this order in a lattice matching manner. The spacer layer includes an AlGaN layer. An AlN mixed crystal ratio of a region of the spacer layer in contact with the channel layer is higher than the remaining region.

JP H11-261051 A discloses various layer structures to improve electric characteristics by increasing and decreasing, in the layer thickness direction, an Al composition ratio of an AlₓGa₁₋ₓN barrier layer (barrier layer) formed on a GaN channel layer.

In the invention disclosed in JP 2004-200711 A, in the case where AlN is used for a spacer layer, that is, the above-described second binary compound semiconductor layer, since the AlN has a very large band gap of 6.2 eV, considering that current injection from the barrier layer to a channel layer is blocked, and a heterostructure does not function when the layer thickness becomes too thick, the film thickness is set to 1 molecular layer or more and 4 molecular layers or less. Consequently, while maintaining steepness on a joint interface, sufficient carrier transport by a tunnel effect can be carried out.

In the invention disclosed in JP 2003-229439 A, the AlN mixed crystal ratio is increased only in a boundary region with a channel layer, not an entire spacer layer. That is, by increasing the AlN mixed crystal ratio while keeping the AlN mixed crystal ratio to a thickness at which lattice relaxation does not occur, the effect of applying a piezoelectric field to the channel layer is greatly increased. By increasing the AlN mixed crystal ratio in the boundary region, a conduction band bottom energy level (Ec) on the spacer layer side increases, and a conduction band discontinuity value can be increased. Consequently, a spontaneous polarization effect can be also enhanced. As a result, a triangular potential can be formed deep and narrow on the channel layer side as compared with the case where the spacer layer is formed with a uniform composition, and the electron concentration in a two-dimensional electron gas (2 DEG) layer is increased, and also element output can be increased.

In the invention disclosed in JP H11-261051 A, a remarkable decrease in an appeared electron mobility can be prevented or greatly reduced by increasing an Al composition X of the AlₓGa₁₋ₓN barrier layer intended to increase a two-dimensional electron concentration which can be induced in a channel in an AlₓGa₁₋ₓN/GaN HEMT, and the performance and output of a device can be increased by increasing a product of an electron concentration and the electron mobility.

As described above, any of the above-described inventions can be said to be a useful technique in a HEMT structure. However, further improvements in characteristics are required while maintaining the advantages of such a thin spacer layer including a nitride containing Al.

### SUMMARY OF THE INVENTION

In view of the above problems, an object of the present invention is to provide a nitride semiconductor substrate having a spacer layer and suitable for a higher performance nitride semiconductor device.

In the nitride semiconductor substrate according to the present invention, an electron transit layer, an intermediate layer, and an electron supply layer are laminated in this order. The electron transit layer includes a nitride semiconductor of a first group 13 element. The intermediate layer includes a nitride semiconductor of the first group 13 element and a second group 13 element. The electron supply layer includes a nitride semiconductor of the first group 13 element and the second group 13 element. The nitride semiconductor substrate has a profile in which an atomic ratio of the second group 13 element with respect to the total of the first group 13 element and the second group 13 element increases in the thickness direction of the intermediate layer from an interface between the electron transit layer and the intermediate layer, and the atomic ratio decreases after a maximum (peak) value is obtained in the intermediate layer.

By having such a structure, in the nitride semiconductor substrate according to the present invention, in an intermediate layer which has improved electron mobility and functions as a spacer layer, the maximum value of an atomic ratio of a second group 13 element, for example, Al does not have a constant region in the thickness direction, and the maximum value becomes a peak shape. As a result, a ratio of the AlN layer with high insulating property decreases, and a series resistance between an electrode and a channel becomes lower than that in the conventional technique, and a series resistance component of a transistor can be reduced.

In the nitride semiconductor substrate according to the present invention, preferably, the atomic ratio of the second group 13 element with respect to a total of the first group 13 element and the second group 13 element in the maximum (peak) value is 50% or more and less than 100%. In addition, it is preferable that the first group 13 element is Ga, and the second group 13 element is Al.

The nitride semiconductor substrate is used in the nitride semiconductor HEMT according to the present invention.

According to the present invention, a nitride semiconductor substrate can be provided which can reduce the series resistance between an electrode and a channel, in comparison with a conventional spacer layer structure, while keeping high electron mobility, and consequently reduce a series resistance component of a transistor.

### BRIEF DESCRIPTION OF THE DRAWING

FIG. 1 is a schematic cross-sectional view illustrating an embodiment of a nitride semiconductor substrate according to the present invention;

FIG. 2 is a schematic diagram schematically illustrating an Al atomic ratio profile of an intermediate layer in a preferred embodiment of the nitride semiconductor substrate according to the present invention;

FIG. 3 is a schematic diagram schematically indicating an Al atomic ratio profile according to an embodiment of the prior art;

FIG. 4 indicates cross-sectional STEM observation results of the vicinity of an electron supply layer/intermediate layer/electron transit layer according to Example 1, in which (A) indicates a bright-field STEM image, and (B) indicates a HAADF-STEM image;

FIG. 5 is a diagram indicating results obtained by STEM-EDS analysis of the vicinity of the electron supply layer/intermediate layer/electron transit layer according to Example 1; and

FIG. 6 is a diagram indicating results obtained by STEM-EDS analysis of the vicinity of the electron supply layer/intermediate layer/electron transit layer according to Example 2.

### DESCRIPTION OF THE PREFERRED EMBODIMENTS

Hereinafter, the present invention will be described in detail with reference to the drawings.

In the nitride semiconductor substrate according to the present invention, an electron transit layer, an intermediate layer, and an electron supply layer are laminated in this order. The electron transit layer includes a nitride semiconductor of a first group 13 element. The intermediate layer includes a nitride semiconductor of the first group 13 element and a second group 13 element. The electron supply layer includes a nitride semiconductor of the first group 13 element and the second group 13 element. The nitride semiconductor substrate has a profile in which an atomic ratio of the second group 13 element with respect to the total of the first group 13 element and the second group 13 element increases in the thickness direction of the intermediate layer from an interface between the electron transit layer and the intermediate layer, and the atomic ratio decreases after a maximum (peak) value is obtained in the intermediate layer.

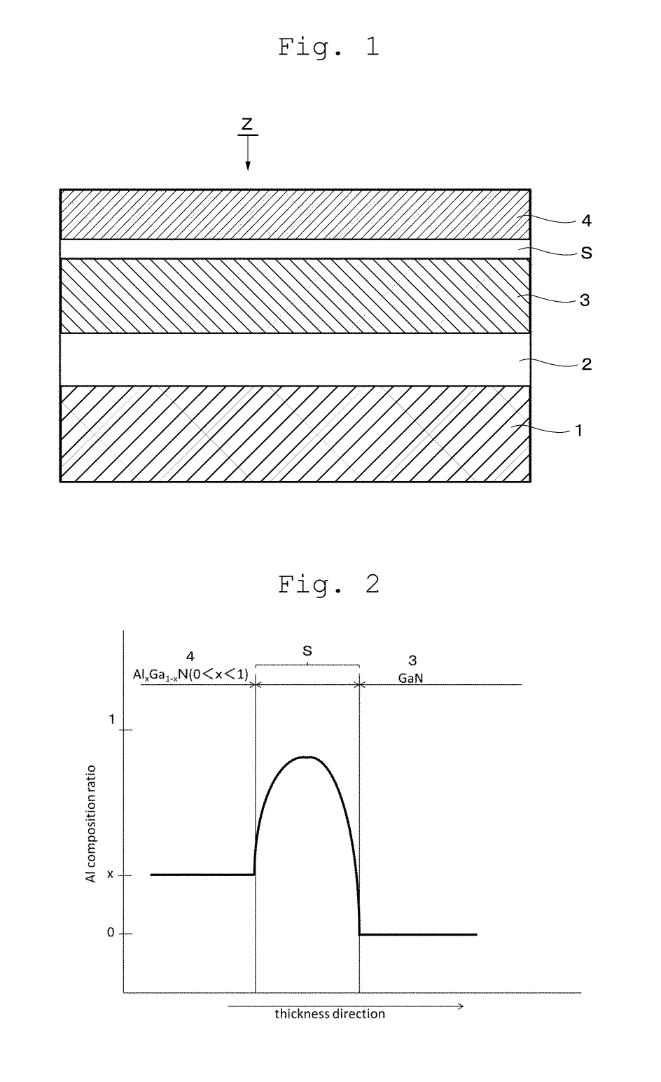

FIG. 1 is a schematic cross-sectional view indicating an embodiment of the nitride semiconductor substrate according to the present invention. In all of the drawings indicated in the present invention, shapes are schematically simplified and emphasized for explanation, and the shapes, dimensions, and ratios of details are different from the actual shapes, dimensions, and ratios.

A nitride semiconductor substrate Z indicated in FIG. 1 has a buffer layer 2, an electron transit layer 3, an intermediate layer S, and an electron supply layer 4 formed in this order on a base substrate 1. Although not illustrated, a cap layer and an electrode are further provided to form a HEMT.

The present invention exhibits particularly preferable characteristics in the HEMT having a heterointerface and using two-dimensional electron gas generated in the vicinity of the interface as a current path. Thus, the base substrate 1 and the buffer layer 2 are not particularly limited in materials, physical properties, structures, and manufacturing methods thereof, and widely known methods can be used.

Examples of the base substrate 1 include such as silicon single crystal, silicon carbide, sapphire, and GaN. In these materials, silicon single crystal tends to be disadvantageous in terms of a withstand voltage in a vertical direction as compared with such as silicon carbide and sapphire having higher insulating property than that of silicon single crystal. However, in the present invention, even in the case where silicon single crystal is used in the base substrate 1, effects thereof can be remarkably exhibited, and it can be said that silicon single crystal is particularly preferable.

As the buffer layer 2, for example, the buffer layer structure disclosed in JP 5159858 B2 or JP 5188545 B2 can be used. Specifically, a layer in which the first layer includes AlN having a thickness of 50 to 200 nm, and the second layer includes AlGaN having a thickness of 100 to 300 nm, and a multilayer buffer layer in which an AlₓGa₁₋ₓN single crystal layer (0.6≤x≤1.0) and an Al_{y}Ga_{1-y}N single crystal layer (0.1≤y≤0.5) are alternately and repeatedly laminated in this order from a substrate side, the AlₓGa₁₋ₓN single crystal layer (0.6≤x≤1.0) containing carbon at 1×10¹⁸ to 1×10²¹ atoms/cm³, the Al_{y}Ga_{1-y}N single crystal layer (0≤y≤0.5) containing carbon at 1×10¹⁷ to 1×10²¹ atoms/cm³, can be used. Further, if a high resistance buffer layer, for example, a GaN layer having a carbon concentration of about 1×10¹⁸ to 3×10¹⁸ atoms/cm³ and a thickness of about 100 to 200 nm is in contact with the electron transit layer 3, it is particularly preferable since a withstand voltage in the vertical direction is improved by the GaN layer.

In the present invention, the electron transit layer 3 including a first group 13 element and the electron supply layer 4 including a first group 13 element and a second group 13 element are used. Group 13 elements are gallium (Ga), aluminum (Al), indium (In), and the like. In the present invention, the first group 13 element is any one of Ga, Al and In, the second group 13 element is any one of Ga, Al and In and other than the first group 13 element. A combination that the first group 13 element is Ga, and the second group 13 element is Al is preferable in terms of high degree of freedom in substrate design.

The electron transit layer 3 and the electron supply layer 4 are not particularly restricted in layer thickness, and the electron transit layer 3 is generally 0.3 to 3.0 μm, and the electron supply layer 4 is 10 to 100 nm. Further, the electron supply layer 4 may be doped with various elements. Examples of the various elements include carbon, phosphorus, magnesium, silicon, iron, oxygen, hydrogen, and the like.

In the present invention, the intermediate layer S is provided between the electron transit layer 3 and the electron supply layer 4. This intermediate layer S has a function as a spacer layer in the prior art and aims at achieving both high output and high electron mobility by increasing the concentration of two-dimensional electron gas in a HEMT.

In particular, in the present invention, the atomic ratio of the second group 13 element with respect to a total of the first group 13 element and the second group 13 element in the intermediate layer S has a profile shape that increases from an interface between the electron transit layer and the intermediate layer toward the thickness direction of the intermediate layer and decreases after the maximum (peak) value is obtained in the intermediate layer.

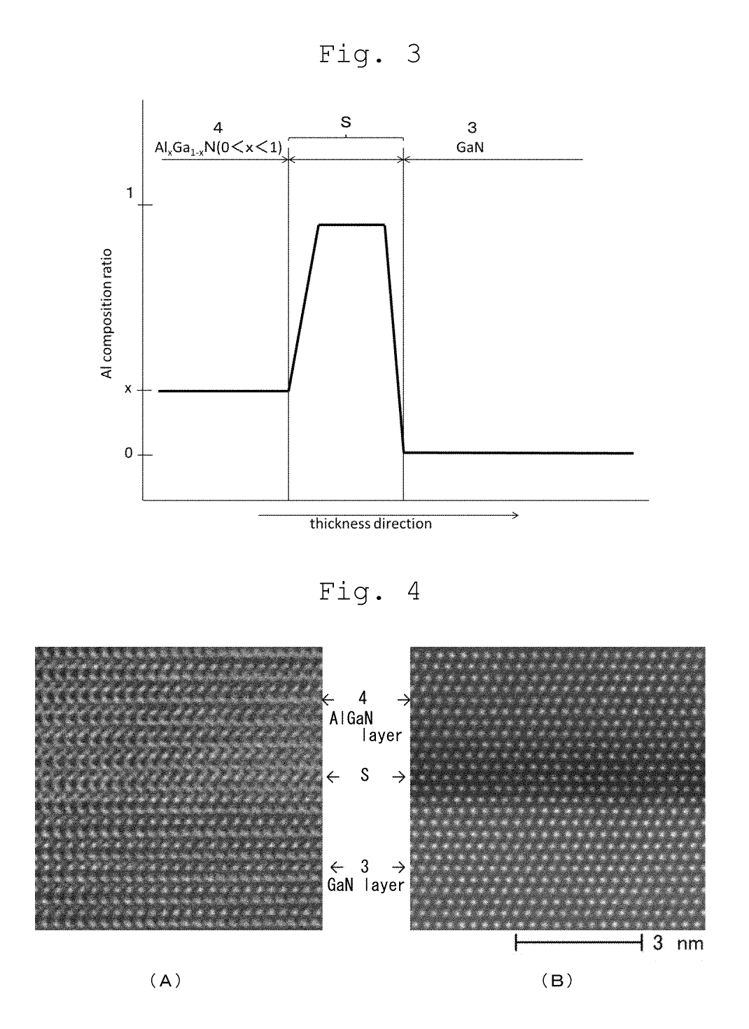

FIG. 2 is a schematic diagram illustrating an Al atomic ratio profile of the intermediate layer S in a preferred embodiment of the nitride semiconductor substrate Z according to the present invention. The curve in FIG. 2 is schematically indicated and is not limited to this form.

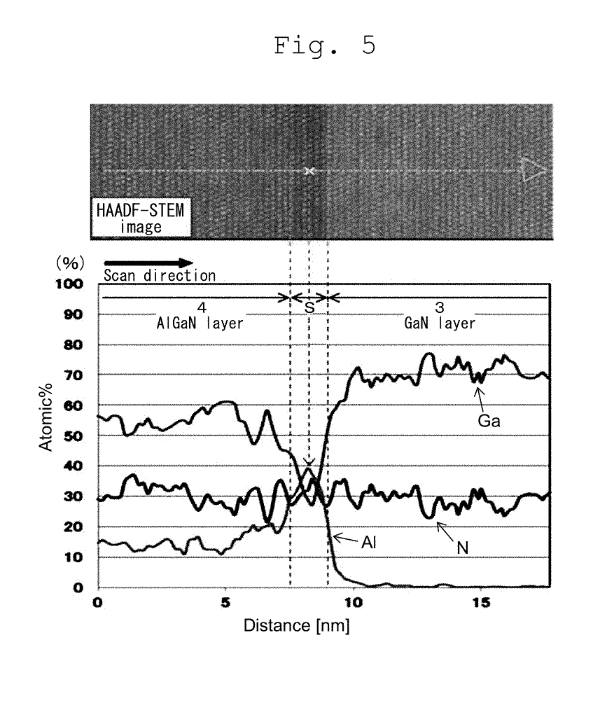

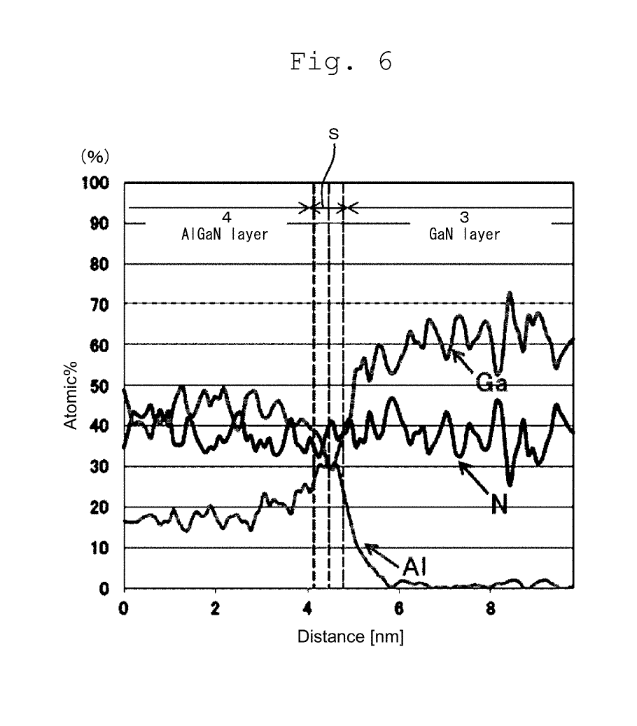

Such a configuration is specified by observing a cross section of the nitride semiconductor substrate Z with a scanning transmission electron microscope (STEM) and performing element analysis by energy dispersive X-ray spectroscopy (EDS). FIG. 4 indicates cross-sectional STEM observation results of the vicinity of the electron supply layer/intermediate layer/electron transit layer. FIG. 5 indicates a result obtained by STEM-EDS analysis of the vicinity of the electron supply layer/intermediate layer/electron transit layer in a preferred embodiment of the nitride semiconductor substrate Z according to the present invention.

The numerical value obtained by EDS is merely a reference value because of its measurement principle. However, by correcting the value by using a standard sample, an existence ratio of different elements is accurately reflected, and in the present invention, distributions of target Al can be accurately known.

As indicated in FIG. 2, the intermediate layer S according to the present invention has a first feature that it has a “peak” of an Al atomic ratio. Here, the peak can be obtained by specifying a portion having the maximum atomic ratio in FIG. 5.

In FIG. 5, the interface between the electron transit layer 3 and the intermediate layer S is positioned at a half position in the thickness direction between a position where an Al atomic ratio in the electron transit layer 3 starts to abruptly increase and the peak which is the maximum value (indicated by dotted lines in FIG. 5). FIG. 5 indicates the atomic ratio of each atom in the case where the total of three elements of Al, Ga, and N is 100%. However, in the case where the total of Al and Ga is converted as 100%, at the peak position of the Al atomic ratio of the intermediate layer S in FIG. 5, the atomic ratio of Al is approximately 62% (the peak position is indicated by an arrow in FIG. 5).

When an AlN layer, that is, a layer having x=1 in AlₓGa₁₋ₓN (0≤x≤1) is thick in the intermediate layer S, the electron mobility decreases. As a result, conventionally, the thickness of a spacer layer is extremely reduced, for example, 1 to 4 molecular layers, or only a part of the spacer layer is made of AlN.

On the other hand, if the spacer layer includes an extremely thin AlN layer or a thin layer which includes AlN locally as described in JP 2004-200711 A, JP 2003-229439 A, and JP H11-261051 A, it is possible to achieve a high electron mobility recently required for HEMT.

Then, the inventors of the present invention have further studied about a thin spacer layer and consequently have found that a characteristic structure which includes nitrides of Al and Ga and has a peak instead of having a region in which an atomic ratio of Al is constant has substantially the same electron mobility as compared with the spacer layer according to the prior art, reduces a series resistance between an electrode and a channel as compared with conventional techniques, and consequently reduces a series resistance of a device.

When a spacer layer includes the layer of constant Al atomic ratio partly, the electron mobility decreases much. Thus, by setting the Al atomic ratio to a peak shape instead of being constant, it is possible to suppress the influence of the decrease in the electron mobility, and lower a series resistance between an electrode and a channel because of the decrease in the ratio of an AlN layer having a high insulating property.

Here, if it is tried to obtain an effect of increasing the concentration of two-dimensional electron gas in an electron transit layer by inserting a spacer layer, the atomic ratio of Al at the peak needs to be 50% or more. In the present invention, by having the peak shape with an Al atomic ratio of 50% or more in the intermediate layer S, remarkable effects can be obtained that the electron mobility is improved, and the series resistance between an electrode and a channel is reduced, and those effects are not explicitly disclosed in the prior art.

However, in the case where the atomic ratio of Al in the peak is 100%, that is, when the peak is formed only of AlN, there is a possibility that the influence of the decrease in the electron mobility offsets the above-described effects and become apparent. Thus, the peak is preferably formed of AlGaN having Al at less than 100%, in other words, AlGaN having a high Al atomic ratio.

Note that the invention described in claim 6 of JP H11-261051 A is similar to the present invention, and as a further specific embodiment, an embodiment indicated in FIG. 3 is disclosed in claim 7 of JP H11-261051 A. However, in the present invention, by having the peak shape, in which an Al atomic ratio is not constant and 50% or more, in the intermediate layer S, remarkable effects can be obtained that electron mobility is improved, and a series resistance between an electrode and a channel is reduced, and those effects are not explicitly disclosed in the prior art.

It is more preferable that the Al atomic ratio in the peak is 2 times or more and 4 times or less the Al atomic ratio in the electron supply layer 4. In the electron supply layer 4, the Al atomic ratio is constant in the thickness direction. However, if this ratio and the atomic ratio at the above-described peak in the intermediate layer S are too far away from each other, the electron mobility may decrease.

In the present invention, when the Al atomic ratio of the electron supply layer 4 is appropriately designed to be 10% or more and 30% or less, a thickness of the electron supply layer 4 is appropriately designed to be 10 nm to 60 nm.

Here, as indicated in the EDS measurement result in FIG. 5, the interface between the intermediate layer S and the electron supply layer 4 cannot be precisely determined, and the thickness of the intermediate layer S is not strictly specified. Incidentally, if the intermediate layer S is defined as from the interface with the electron transit layer 3 to the region where the atomic ratio of the second group 13 element is 10% or less in the thickness direction, the thickness of the intermediate layer S is 0.5 nm to 5 nm.

In the intermediate layer S, the peak of the Al atomic ratio is included, and the width of the region in which the Al atomic ratio is more than 50% with respect to the total of Al and Ga is preferably 0.5 nm or more and 1.5 nm or less, more preferably 0.5 nm or more and 0.8 nm or less. In other words, this region can be said to be a spacer layer in the strict sense. In a region having a high Al atomic ratio, if the peak is as sharp as possible and narrow in width, improvement of an electron mobility and decrease of a series resistance between an electrode and a channel are more satisfactorily achieved.

Alternatively, a position of the peak is preferably on the side of the electron transit layer 3 from the intermediate point in the thickness direction of the intermediate layer S. This is because the high spontaneous polarization effect obtained by GaN in the electron transit layer 3 and AlN being adjacent to each other becomes high as compared with an embodiment that the peak is positioned on the electron supply layer 4 side from the intermediate point in the thickness direction of the intermediate layer S.

A profile shape according to the Al atomic ratio of the intermediate layer S according to the present invention can be appropriately obtained by a metal organic chemical vapor deposition (MOCVD) method, by optimizing a timing of supply of Al source gas, in addition to adjusting various source gases, a flow rate of carrier gas, and a pressure in a reactor, from immediately after the formation of the electron transit layer 3.

As described above, as well as a substrate having a conventional spacer layer, the nitride semiconductor substrate according to the present invention can improve the electron mobility in two-dimensional electron gas, increase a speed of the transistor, and reduce a series resistance between an electrode and a channel. As a result, the nitride semiconductor substrate is suitable for a nitride semiconductor device which can reduce a series resistance component of a transistor.

### EXAMPLES

Hereinafter, the present invention will be specifically described based on examples. However, the present invention is not limited thereto.

[Common Experimental Conditions]

A silicon single crystal substrate having a diameter of 6 inches, a thickness of 1000 μm, a p type specific resistance of 0.01 Ωcm, and a plane orientation (111) is prepared as the base substrate 1. After the substrate is cleaned by a known substrate cleaning method, the substrate is set in an MOCVD apparatus. After a temperature increases, and gas is replaced, a heat treatment is performed at a growth temperature of 1000° C. for 15 minutes, under conditions of a hydrogen 100% atmosphere and a furnace pressure of 135 hPa. Then, a natural oxide film on the surface of the base substrate 1 is removed, and an atomic step of silicon is developed on the surface.

Subsequently, an AlN single crystal having a thickness of 70 nm is formed by using trimethylaluminum (TMAl) and ammonia (NH₃) as source gases. Next, an Al_{0.1}Ga_{0.9}N single crystal layer having a thickness of 300 nm is formed by using trimethylgallium (TMG), TMAl, and NH₃ as source gases by adjusting the growth temperature to 1000° C. and the furnace pressure to 60 hPa. Next, by using TMG, TMAl, and NH₃ as source gases, each of an AlN single crystal layer having a thickness of 5 nm and an Al_{0.1}Ga_{0.9}N single crystal layer having a thickness of 30 nm is alternately laminated in eight layers, an AlGaN single crystal layer having a thickness of 150 nm is formed thereon, and a multilayer structure having a layer thickness of about 2150 nm is formed by repeatedly forming five sets of the laminated layer. In this manner, the buffer layer 2 is formed on the base substrate 1.

A GaN single crystal layer having a thickness of 3000 nm is laminated on the buffer layer 2 as the electron transit layer 3 by adjusting a growth temperature to 1030° C. and a furnace pressure to 200 hPa.

The intermediate layer S is formed on the electron transit layer 3 under the conditions described in Example 1 and Comparative Examples 1 and 2.

Then, an Al_{0.18}Ga_{0.82}N single crystal layer having a thickness of 24 nm is formed on the intermediate layer S by adjusting the growth temperature to 1000° C. and the furnace pressure to 200 hPa as the electron supply layer 4, and further a GaN layer having a thickness of 4 nm is formed as a cap layer. Through the above-described processes, a nitride semiconductor substrate for evaluation is obtained. The thickness and carbon concentration of each layer formed by vapor phase growth are controlled by adjusting a flow rate and supply time of source gases, a substrate temperature, and other known growth conditions.

### Example 1

TMG, TMAl, and NH₃ have been introduced as source gases for 30 seconds at a growth temperature of 1030° C. and a furnace pressure of 200 hPa to form the intermediate layer S on the electron transit layer 3.

### Comparative Example 1

TMG, TMAl, and NH₃ have been introduced as source gases for 30 seconds at a growth temperature of 1030° C. and a furnace pressure of 50 hPa to form the intermediate layer S on the electron transit layer 3.

In this case, in the intermediate layer S, an Al content is considerably increased as compared with Example 1, the maximum (peak) value is not confirmed, and a region with a constant concentration is formed with Al 100% in the thickness direction.

### Reference Example 1

TMG, TMAl, and NH₃ have been introduced as source gases for 30 seconds at a growth temperature of 1030° C. and a furnace internal pressure of 600 hPa to form the intermediate layer S on the electron transit layer 3. In the intermediate layer S, the Al content is significantly reduced as compared with Example 1, and a peak less than Al 50% is formed in the thickness direction.

With respect to the nitride semiconductor substrate obtained in Example 1, Comparative Example 1, and Reference Example 1, cross-sectional observation and elemental analysis have been performed on the intermediate layer S and a portion of the electron transit layer 3 and the electron supply layer 4 adjacent to the intermediate layer S. Conditions of the cross-sectional observation and elemental analysis will be described below.

[Evaluation 1 to STEM Observation]

Each nitride semiconductor substrate has been cleaved, fragments have been sampled from the vicinity of the center of a main surface and sliced by a focused ion beam (FIB) method to obtain a sample for measurement. This sample has been observed at an acceleration voltage of 200 kV by using STEM (scanning transmission electron microscope; JEM-ARM 200F, manufactured by JEOL Ltd.).

[Evaluation 2 to EDS Analysis]

The elemental analysis has been performed using an EDS measuring device (energy dispersive X-ray spectrometer; JED-2300T, manufactured by JEOL Ltd.) attached to the STEM under the measurement conditions of an acceleration voltage of 200 kV, a beam diameter of 0.1 nmφ, and an energy resolution of about 140 eV. After the above-described STEM observation, EDS measurement has been carried out by linearly irradiating the vicinity of the electron supply layer 4/intermediate layer S/electron transit layer 3 in a width range of 20 nm with a 100 point beam. A beam interval has been 0.2 nm, and a measurement time per point has been 1 second.

Here, one point near the center of the main surface of the nitride semiconductor substrate has been sampled to specify the form of the intermediate layer S. Film formation by an MOCVD method can be said to be satisfactory since the film formation is highly accurate. However, the sampling number may be further increased as necessary, for example, by adding two points in the 10 mm inner side from an outer circumference, total three points may be sampled.

As a result of the above-described evaluation, in Example 1, the thickness of the intermediate layer S has been about 1 nm, and a peak having the maximum Al atomic ratio has been included in the spacer layer. From the EDS quantitative analysis result, an atomic ratio in Al and Ga in the peak portion in the nitride semiconductor has been 62:38.

[Evaluation 3, Electron Mobility and Series Resistance Among Electrode-Channel-Electrode]

Next, hall effect measurement by the van der Pauw method has been carried out on the same nitride semiconductor substrate as the substrate on which the STEM observation and the EDS analysis have been carried out, and an electron mobility and a resistance value between the nearest neighbor electrodes have been evaluated. First, the substrate has been diced into chips of 7 mm square, and Ti/Al electrodes of 0.25 mm in diameter have been formed by vacuum deposition at four corners on the electron supply layer 4 of each chip. Next, an alloying heat treatment has been performed at 600° C. for 5 minutes in N₂ atmosphere. Then, a hall effect measurement has been carried out by using HL5500PC manufactured by ACCENT.

As a result, in Example 1, the electron mobility has been 1990 cm²/Vs, and a resistance value between the nearest neighbor electrodes has been 3000 to 4000Ω. On the other hand, in Comparative Example 1, the electron mobility has been 2060 cm²/Vs, and the resistance value between the nearest neighbor electrodes has been 5000 to 6000Ω. In Reference Example 1, the electron mobility has been 1,500 cm²/Vs, and the resistance value between the nearest neighbor electrodes has been 2000 to 3000Ω.

From the above results, it can be said that in Example 1, improvement in the electron mobility and reduction in the series resistance are effectively obtained. On the other hand, in Comparative Example 1, although the electron mobility is about the same as in Example 1, the series resistance between an electrode and a channel is increased. In Reference Example 1, the electron mobility greatly decreases, and the intermediate layer S does not function as a spacer layer. Thus, neither of them is inferior to Example 1.

As a result, the nitride semiconductor substrate according to the present invention is superior in two effects. One effect is improving the electron mobility, and another effect is reducing the series resistance among the electrode-channel-electrode and reducing the series resistance component of a transistor.

### Example 2

TMG, TMAl, and NH₃ have been introduced as source gases for 15 seconds at a growth temperature of 1030° C. and a furnace internal pressure of 200 hPa to form the intermediate layer S having a thickness of 0.5 nm on the electron transit layer 3.

### Example 3

TMG, TMAl, and NH₃ have been introduced as source gases for 60 seconds at a growth temperature of 1030° C. and a furnace internal pressure of 200 hPa to form the intermediate layer S having a thickness of 2 nm on the electron transit layer 3.

Regarding the above-described Examples 2 and 3, the same evaluation as in Example 1 has been carried out. FIG. 6 indicates results of Example 2 obtained by STEM-EDS analysis as in FIG. 5.

As a result, in Example 1, the electron mobility is 1990 cm²/Vs, and the resistance value between the nearest neighbor electrodes is 3000 to 4000Ω. In Example 2, the electron mobility is 1800 cm²/Vs, the resistance value between the nearest neighbor electrodes is 2500 to 3500Ω. In Example 3, the electron mobility is 2020 cm²/Vs, and the resistance value between the nearest neighbor electrodes is 3500 to 4500Ω.

According to the above results, regarding the thickness of the intermediate layer S, Example 3 in which the thickness is thicker than that of Example 1 is inferior in terms of the series resistance between an electrode and a channel. Also, Example 2 in which the thickness is thinner than that of Example 1 is superior in terms of the series resistance between an electrode and a channel and is inferior in terms of the mobility.

1. A nitride semiconductor substrate, wherein
an electron transit layer comprising a nitride semiconductor of a first group 13 element,
an intermediate layer comprising a nitride semiconductor of the first group 13 element and a second group 13 element, and
an electron supply layer comprising a nitride semiconductor of the first group 13 element and the second group 13 element are laminated in this order, and
the nitride semiconductor substrate has a profile, in which an atomic ratio of the second group 13 element with respect to a total of the first group 13 element and the second group 13 element increases in the thickness direction of the intermediate layer from an interface between the electron transit layer and the intermediate layer, and the atomic ratio decreases after a maximum peak value is obtained in the intermediate layer.

2. The nitride semiconductor substrate according to claim 1, wherein the atomic ratio of the second group 13 element with respect to the total of the first group 13 element and the second group 13 element in the maximum peak value is 50% or more and less than 100%.

3. The nitride semiconductor substrate according to claim 2, wherein a thickness of the intermediate layer is 0.5 nm or more and 1.5 nm or less.

4. The nitride semiconductor substrate according to claim 1, wherein the first group 13 element is Ga, and the second group 13 element is Al.

5. The nitride semiconductor substrate according to claim 2, wherein the first group 13 element is Ga, and the second group 13 element is Al.

6. The nitride semiconductor substrate according to claim 3, wherein the first group 13 element is Ga, and the second group 13 element is Al.

7. A nitride semiconductor HEMT using the nitride semiconductor substrate according to claim 1.

8. A nitride semiconductor HEMT using the nitride semiconductor substrate according to claim 2.

9. A nitride semiconductor HEMT using the nitride semiconductor substrate according to claim 3.

10. A nitride semiconductor HEMT using the nitride semiconductor substrate according to claim 4.
